(19) United States
(12) Patent Application Publication
(10) Pub. No.: US 2017/0294540 A1
(43) Pub. Date: Oct. 12, 2017

(54) SEMICONDUCTOR STRUCTURE AND METHOD FOR MANUFACTURING THE SAME

(71) Applicant: UNITED MICROELECTRONICS CORP., Hsinchu (TW)

(72) Inventors: I-Cheng Hu, Kaohsiung City (TW); Kai-Hsiang Wang, Taichung City (TW); Tien-I Wu, Taoyuan City (TW); Yu-Shu Lin, Pingtung City (TW); Shu-Yen Chan, Yuanlin City (TW)

(21) Appl. No.: 15/095,484

(22) Filed: Apr. 11, 2016

(51) Int. Cl. H01L 29/78; H01L 29/08; H01L 29/40; H01L 29/49; H01L 29/161; H01L 29/66; H01L 29/45

(52) U.S. Cl. CPC H01L 29/7848; H01L 29/665; H01L 29/0847; H01L 29/456; H01L 29/4975; H01L 29/161; H01L 29/6653; H01L 29/66636; H01L 29/401; H01L 29/7845

(57) ABSTRACT

A semiconductor structure and a method for manufacturing the same are provided. The semiconductor includes a substrate, two source/drain regions, a gate structure and two salicide layers. The two source/drain regions are partially disposed in the substrate each with a substantially flat top surface higher than a top surface of the substrate, and the two source/drain regions are separated from each other. The two source/drain regions are formed of an epitaxial material. The gate structure is disposed on the substrate between the two source/drain regions. The two salicide layers are disposed on the substantially flat top surfaces of the two source/drain regions, respectively.

### TECHNICAL FIELD

The disclosure relates to a semiconductor structure and a method for manufacturing the same. More particularly, the disclosure relates to a semiconductor structure comprising source/drain regions formed of an epitaxial material and a method for manufacturing the same.

### BACKGROUND

Strain engineering has been used in the semiconductor devices for further improving the performance. For example, a PMOS device may have a better performance by applying a compressive strain to the channel. While for a NMOS device, a tensile strain is preferably applied to the channel. One method of applying the strain to the channel is to form a stress-applying film, such as a SiN film, over the structure. Another method is to introduce dopants into the source/drain areas. Still another method is to form epitaxial structures in the source/drain areas instead of the conventional source/drain regions.

### SUMMARY

This disclosure provides a semiconductor structure comprising epitaxial structures in the source/drain areas (i.e. source/drain regions formed of an epitaxial material) and a method for manufacturing the same. The semiconductor structure according to embodiments has improved electrical performance.

According to some embodiments, a semiconductor comprises a substrate, two source/drain regions, a gate structure and two salicide layers. The two source/drain regions are partially disposed in the substrate each with a substantially flat top surface higher than a top surface of the substrate, and the two source/drain regions are separated from each other. The two source/drain regions are formed of an epitaxial material. The gate structure is disposed on the substrate between the two source/drain regions. The two salicide layers are disposed on the substantially flat top surfaces of the two source/drain regions, respectively.

According to some embodiments, a method for manufacturing a semiconductor structure comprises the following steps. First, a preliminary structure is provided. The preliminary structure comprises a substrate and a gate structure. The substrate comprises two source/drain areas which are separated from each other. The gate structure is formed on the substrate between the two source/drain areas. Then, a disposable layer is formed on the preliminary structure. The disposable layer is thermally treated. Two sacrificial spacers are formed on two sidewalls of the gate structure. Two source/drain regions are formed partially in the substrate at the two source/drain areas, respectively. The two source/drain regions are formed of an epitaxial material. Thereafter, two salicide layers are formed on substantially flat top surfaces of the two source/drain regions, respectively, wherein the substantially flat top surfaces are higher than a top surface of the substrate.

### BRIEF DESCRIPTION OF THE DRAWINGS

FIG. 1 illustrates a semiconductor structure according to embodiments.

FIGS. 2A-2J illustrate a semiconductor structure at various stages of manufacturing according to embodiments.

FIG. 3 illustrates a comparative semiconductor structure at a stage of manufacturing.

FIGS. 4A-4B illustrate the current characteristics of a semiconductor structure according to embodiments and of a comparative semiconductor structure thereof.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. For clarity, the elements in the figures may not reflect their real sizes. Further, in some figures, undiscussed components may be omitted. It is contemplated that elements and features of one embodiment may be beneficially incorporated in another embodiment without further recitation.

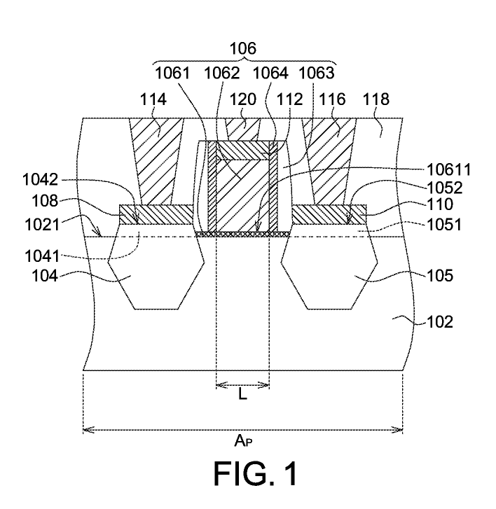

FIG. 1 illustrates a semiconductor structure according to embodiments. Particularly, in FIG. 1, a PMOS area A_{P} of the semiconductor structure is exemplarily illustrated. The semiconductor structure comprises a substrate 102, two source/drain regions 104 and 105, and a gate structure 106.

The two source/drain regions 104 and 105 are partially disposed in the substrate 102. The two source/drain regions 104 and 105 are separated from each other. The two source/drain regions 104 and 105 have substantially flat top surfaces 1042 and 1052, respectively. The substantially flat top surfaces 1042 and 1052 are higher than a top surface 1021 of the substrate 102. More specifically, the two source/drain regions 104 and 105 have top portions 1041 and 1051 with substantially trapezoidal cross-section, respectively, and the top portions 1041 and 1051 have the substantially flat top surfaces 1042 and 1052, respectively. The two source/drain regions 104 and 105 are formed of an epitaxial material, such as SiGe.

The gate structure 106 is disposed on the substrate 102 between the source/drain regions 104 and 105. The gate structure 106 may comprise a gate dielectric 1061 and a gate electrode 1062. The gate electrode 1062 is disposed on the gate dielectric 1061. The substantially flat top surfaces 1042 and 1052 of the source/drain regions 104 and 105 may be higher than a top surface 10611 of the gate dielectric 1061. In some embodiments, the gate electrode 1062 has a length L of 0.09 μm to 0.15 μm. The gate structure 106 may further comprise spacers 1063 and liner spacers 1064 on sidewalls of the gate electrode 1062.

The semiconductor structure further comprises two salicide layers 108 and 110. The two salicide layers 108 and 110 are disposed on the substantially flat top surfaces 1042 and 1052 of the two source/drain regions 104 and 105, respectively. The semiconductor structure may further comprise another salicide layer 112 on the gate electrode 1062.

The semiconductor structure may further comprise two contacts 114 and 116 connected to the two source/drain regions 104 and 105, respectively. The contacts 114 and 116 typically are disposed through a dielectric layer 118 of the semiconductor structure, which is disposed over the components (except the contacts 114 and 116) described above. The semiconductor structure may further comprise another contact 120 disposed in the dielectric layer 118 and connected to the gate structure 106.

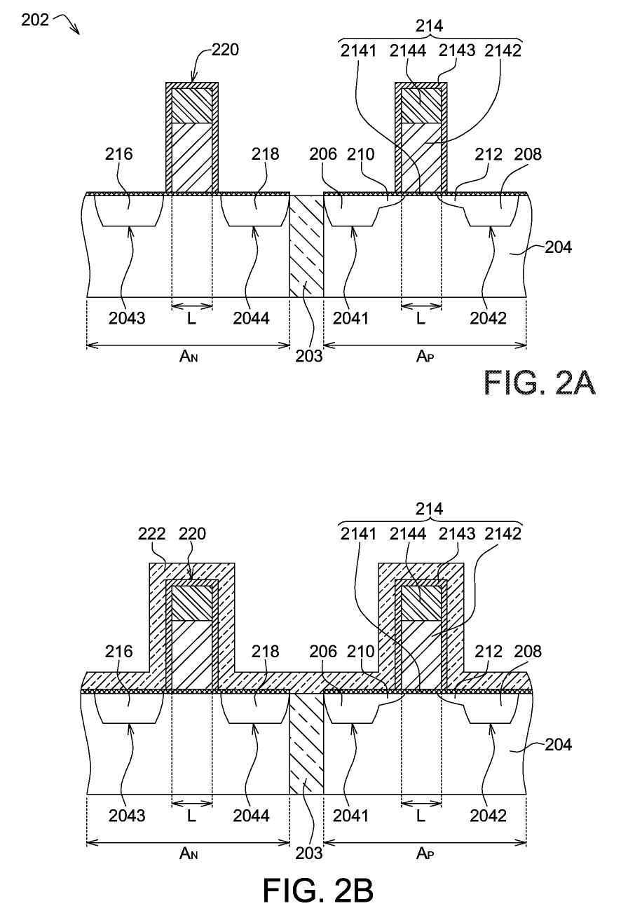

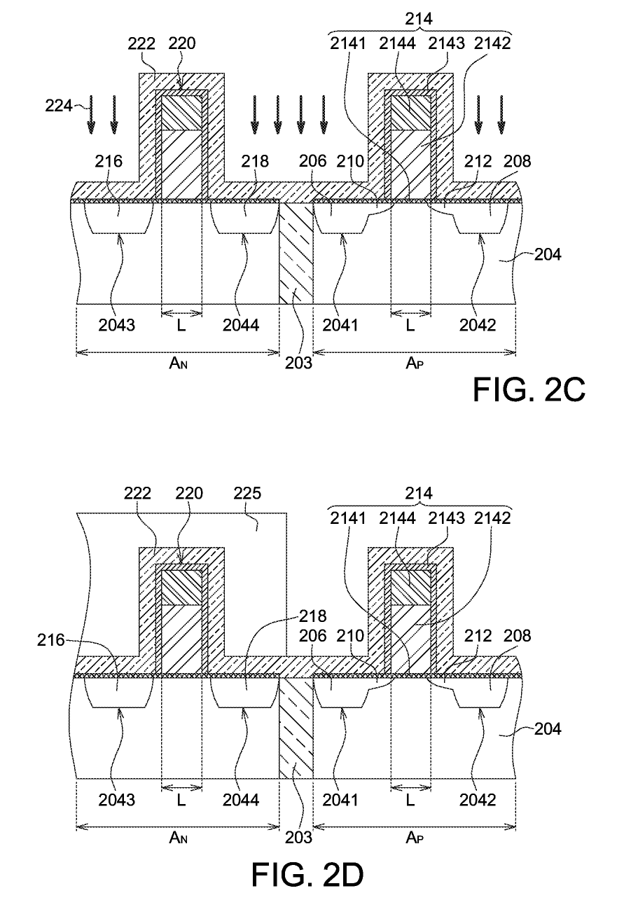

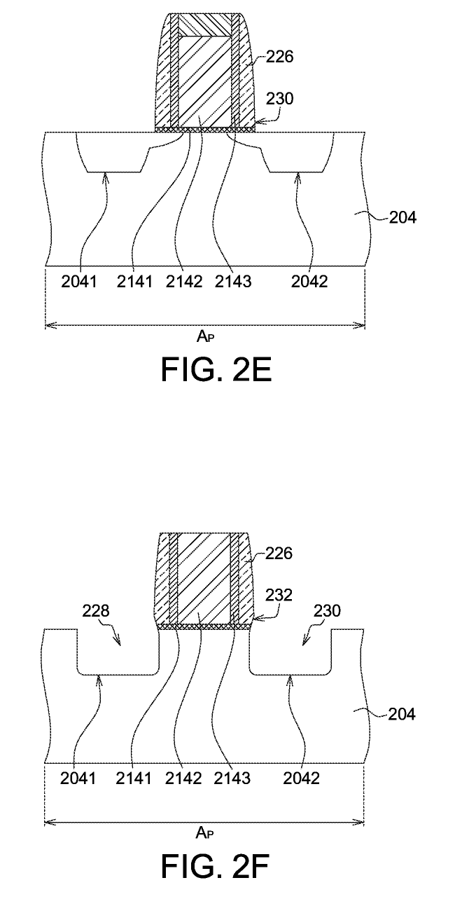

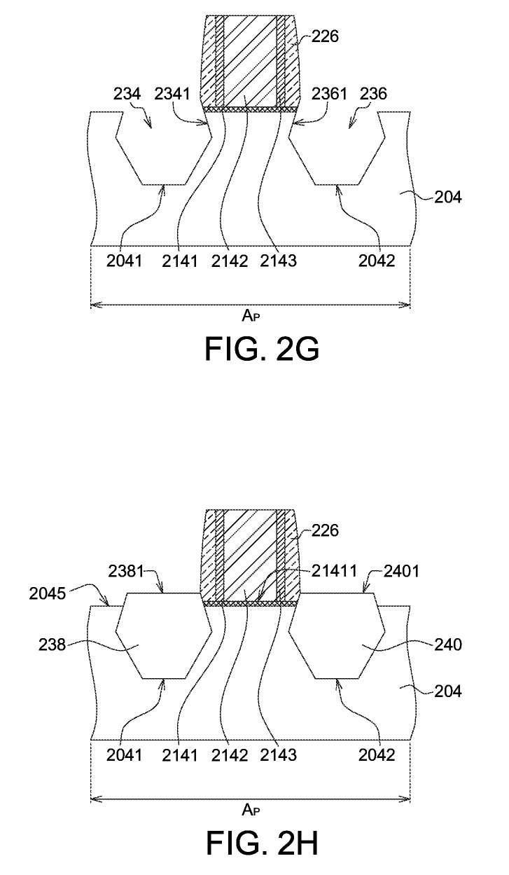

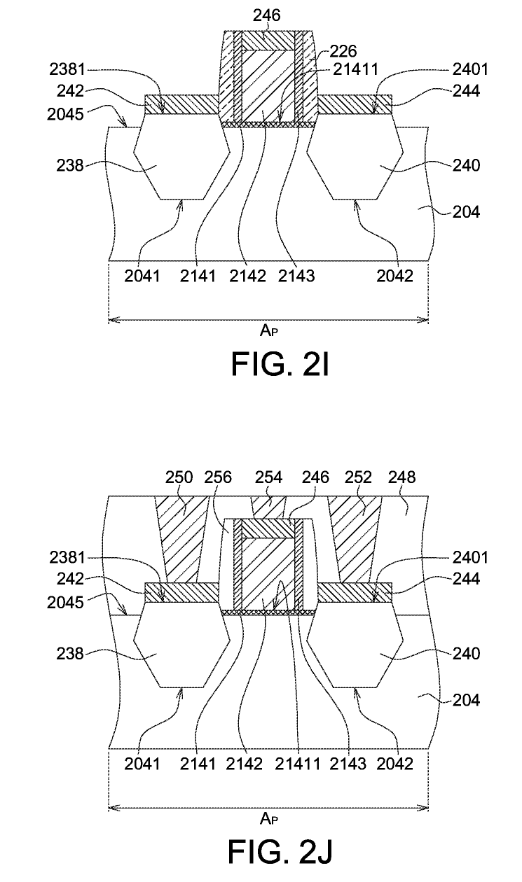

FIGS. 2A-2J illustrate a semiconductor structure at various stages of manufacturing according to embodiments. Referring to FIG. 2A, a preliminary structure 202 is provided. According to some embodiments, as shown in FIG. 2A, the preliminary structure 202 may, for example, have a PMOS area A_{P} and a NMOS area A_{N} isolated by an isolation structure 203.

The preliminary structure 202 comprises a substrate 204 comprising two source/drain areas 2041 and 2042 which are separated from each other, and a gate structure 214 formed on the substrate 204 between the two source/drain areas 2041 and 2042. In the case shown in FIG. 2A, the two source/drain areas 2041 and 2042 and the gate structure 214 are included in the PMOS area A_{P}. Still in the PMOS area A_{P}, the preliminary structure 202 may further comprise two implanted regions 206 and 208 formed in the two source/drain areas 2041 and 2042, respectively. In addition, the preliminary structure 202 may further comprise two lightly-implanted regions 210 and 212 each of which is formed between the gate structure 214 and one of the implanted regions 206 and 208. The gate structure 214 comprises a gate dielectric 2141 and a gate electrode 2142 formed on the gate dielectric 2141. In some embodiments, the gate electrode 1062 has a length L of 0.09 μm to 0.15 μm. The gate structure 214 may further comprise a layer 2143 formed of a material for liner spacers, and a hard mask layer 2144. The hard mask layer 2144 is formed on the gate electrode 1062. The layer 2143 covers the hard mask 2144 and the gate electrode 1062.

The preliminary structure 202 may comprise corresponding components in the NMOS area A_{N}. More specifically, in the NMOS area A_{N}, the preliminary structure 202 may comprise two implanted regions 216 and 218 formed in two other source/drain areas 2043 and 2044 of the substrate, respectively, a gate structure 220 formed on the substrate 204 between the two source/drain areas 2043 and 2044. The implanted regions 216 and 218 have opposite doping type to the implanted regions 206 and 208. The gate structure 220 may be substantially the same as the gate structure 214. Optionally, the preliminary structure 202 may further comprise two lightly-implanted regions (not shown) each of which is formed between the gate structure 220 and one of the implanted regions 216 and 218. Alternatively, the lightly-implanted regions may be formed in a later process.

Referring to FIG. 2B, a disposable layer 222 is formed on the preliminary structure 202. Here, the disposable layer 222 may be formed on both the PMOS area A_{P} and the NMOS area A_{N}. The disposable layer 222 may be formed of SiN. Then, as shown in FIG. 2C, the disposable layer 222 is thermally treated. The thermal treatment 224 may be a rapid thermal process (RTP). For example, the thermal treatment 224 of the disposable layer 222 may be conducted at 900° C. to 1000° C. with a processing gas comprising N₂. The disposable layer 222 is modified by the thermal treatment 224.

After the thermal treatment of the disposable layer 222, the modified disposable layer 222 is partially removed to form further components, such as two sacrificial spacers 226 on two sidewalls of the gate structure 214. Referring to FIG. 2D, a mask 225, such as a photo resist, is formed covering the NMOS area A_{N}. Then, portions of the disposable layer 222 are removed from the PMOS area A_{P} such that the source/drain areas 2041 and 2042 and the gate structure 214 are exposed and the two sacrificial spacers 226 formed of the disposable layer 222 are remained on the sidewalls of the gate structure 214, as shown in FIG. 2E. Further, the remained disposable layer 222 in the NMOS area A_{N}, which is protected by the mask 225, may be used to provide the strain to the channel of the NMOS area A_{N}.

Thereafter, two source/drain regions 238 and 240 are formed partially in the substrate 204 at the two source/drain areas 2041 and 2042, respectively, wherein the two source/drain regions 238 and 240 are formed of an epitaxial material.

In the beginning, two recesses are formed at the two source/drain areas 2041 and 2042, respectively. Referring to FIG. 2F, first, a dry etch step may be carried out. Two recesses 228 and 230 are formed at the two source/drain areas 2041 and 2042, respectively. It is noted that, after the dry etch step, outer bottom portions 232 of the two sacrificial spacers 226, which are formed of the modified disposable layer 222, may be removed.

Then, referring to FIG. 2G, a wet etch step may be carried out. After the wet etch step, the two recesses 228 and 230 are further expanded and form two recesses 234 and 236 each having a hexagonal cross-section. The two recesses 234 and 236 have sides 2341 and 2361 extending along corresponding one of the two sacrificial spacers 226. This may be because the material of the disposable layer 222 and the material of the gate dielectric 2141, such as SiN, is densified by the thermal treatment 224 and thereby has a lower etching rate compared to the material of the substrate 204, such as Si. Thus, during the two-step etching process, the disposable layer 222 and the gate dielectric 2141 may be etched from the bottom because the substrate 204 underneath had been etched. As such, the structure shown in FIG. 2G is obtained.

Referring to FIG. 2H, an epitaxial material is grown in the recesses 234 and 236 to form the two source/drain regions 238 and 240. The epitaxial material may be SiGe, of which the Si:Ge ratio is adjustable. The two source/drain regions 238 and 240 have substantially flat top surfaces 2381 and 2401, respectively. As shown in FIG. 2H, the substantially flat top surfaces 2381 and 2401 may be higher than a top surface 2045 of the substrate 204. In particular, the substantially flat top surfaces 2381 and 2401 are higher than a top surface 21411 of the gate dielectric 2141.

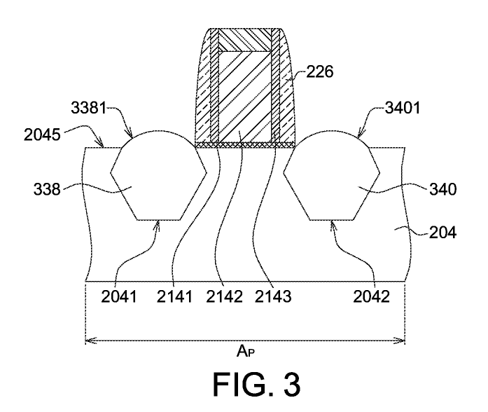

A comparative semiconductor structure is shown in FIG. 3. In this case, no thermal treatment is carried out after the formation of the disposable layer 222. Alternatively, a thermal treatment may be carried out before forming the disposable layer 222 such as for activating the dopants in the source/drain areas 2041 and 2042. As such, the disposable layer 222 is not modified by a thermal treatment, and thus the structure as shown in FIG. 2G is not obtained. Accordingly, instead of growing along sides 2341 and 2361 and forming substantially flat top surfaces 2381 and 2401, the epitaxial material in this case is blocked when growing to the level of the surface 2045 of substrate 204. As such, the source/drain regions 338 and 340 have curved top surfaces 3381 and 3401, which may not be suitable for the following formation of electrical connections.

Referring to FIG. 2I, two salicide layers 242 and 244 are formed on substantially flat top surfaces 2381 and 2401 of the two source/drain regions 238 and 240, respectively, In addition, another salicide layer 246 may be formed on the gate electrode 2142. The salicide layers 242, 244 and 246 may be formed by forming cap layers on the source/drain regions 238 and 240 and the gate electrode 2142, respectively, followed by a thermal treatment to form the salicide layers 242, 244 and 246 at the interfaces. A more uniform salicide layer can be formed on a substantially flat top surface compared to a curved top surface. Accordingly, the method according to embodiments can provide a semiconductor structure with better electrical performance.

Thereafter, other typical processes for the manufacturing of a semiconductor structure may be carried out. For example, as shown in FIG. 2J, two spacers 256 may be formed instead of the two sacrificial spacers 226. A dielectric layer 118 may be formed over the substrate 204. Two contacts 250 and 252 may be formed and connected to the two source/drain regions 238 and 240, respectively. Another contact 254 may be formed and connected to the gate structure 214.

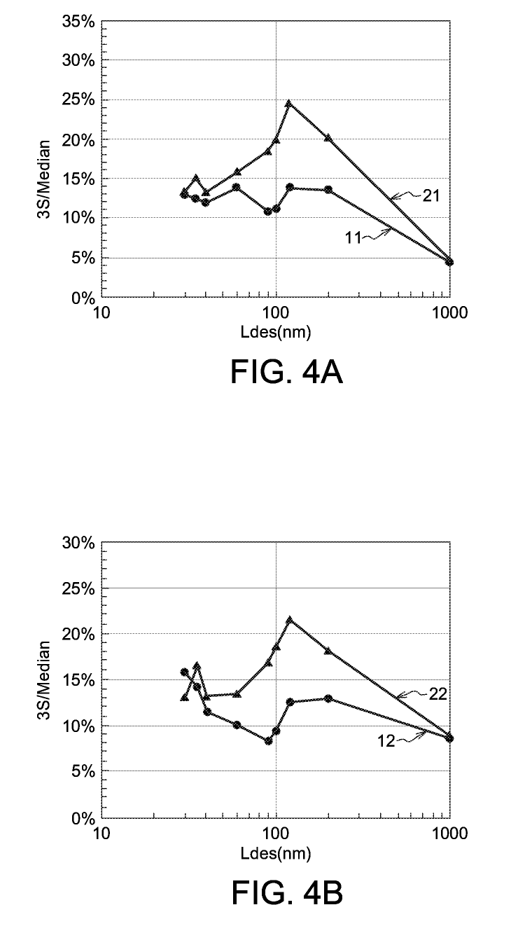

Now referring to FIGS. 4A and 4B, as described above, the method according to embodiments can provide a semiconductor structure with better electrical performance because of the configuration of the source/drain regions. FIG. 4A shows the characteristics of I_{dlin}, and FIG. 4B shows the characteristics of Iₒₙ, wherein the lines 11 and 12 correspond to the semiconductor structure according to embodiments (i.e. with substantially flat top surfaces), and the lines 21 and 22 correspond to a comparative semiconductor structure with curved top surfaces. It can be seen that the current variations of the semiconductor structure according to embodiments are better than the current variations of the comparative semiconductor structure, i.e., in a range of 10% to 15%. The improvement is especially obvious when the gate length is of 90 nm to 150 nm.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A semiconductor structure, comprising:
a substrate;
two source/drain regions partially disposed in the substrate each with a substantially flat top surface higher than a top surface of the substrate, the two source/drain regions separated from each other, the two source/drain regions formed of an epitaxial material;
a gate structure disposed on the substrate between the two source/drain regions, the gate structure comprising a gate dielectric, a gate electrode on the gate dielectric and two spacers on sidewalls of the gate electrode, wherein each of the two spacers, together with the gate dielectric, forms a side inclining inwardly toward the gate electrode and declining inwardly toward the substrate, and the corresponding one of the two source/drain regions has an inclining surface contacting the substrate, the gate dielectric and the side; and
two salicide layers disposed on the substantially flat top surfaces of the two source/drain regions, respectively.

2. The semiconductor structure according to claim 1, wherein the substantially flat top surfaces of the source/drain regions are higher than a top surface of the gate dielectric.

3. The semiconductor structure according to claim 2, wherein the gate electrode has a length of 0.09 μm to 0.15 μm.

4. The semiconductor structure according to claim 3, further comprising:
another salicide layer on the gate electrode.

5. The semiconductor structure according to claim 1, wherein each of the two source/drain regions has a top portion with a substantially trapezoidal cross-section, and the top portion has the substantially flat top surface.

6. The semiconductor structure according to claim 1, wherein the epitaxial material is SiGe.

7. The semiconductor structure according to claim 1, further comprising two contacts connected to the two source/drain regions, respectively.

8. A method for manufacturing a semiconductor structure, comprising:
providing a preliminary structure, the preliminary structure comprising:
a substrate comprising two source/drain areas which are separated from each other; and
a gate structure formed on the substrate between the two source/drain areas, the gate structure comprising a gate dielectric and a gate electrode on the gate dielectric;
forming a disposable layer on the preliminary structure;
thermally treating the disposable layer;
forming two sacrificial spacers on two sidewalls of the gate structure;
forming two source/drain regions partially in the substrate at the two source/drain areas, respectively, wherein the two source/drain regions are formed of an epitaxial material, and wherein each of the two sacrificial spacers, together with the gate dielectric, forms a side inclining inwardly toward the gate structure and declining inwardly toward the substrate, and the corresponding one of the two source/drain regions has an inclining surface contacting the substrate, the gate dielectric and the side; and
forming two salicide layers on substantially flat top surfaces of the two source/drain regions, respectively, wherein the substantially flat top surfaces are higher than a top surface of the substrate.

9. The method according to claim 8, wherein the preliminary structure further comprises two implanted regions formed in the two source/drain areas, respectively.

10. The method according to claim 9, wherein the preliminary structure further comprises two lightly-implanted regions each of which is formed between the gate structure and one of the implanted regions.

11. The method according to claim 8, wherein the substantially flat top surfaces are higher than a top surface of the gate dielectric.

12. The method according to claim 11, wherein the gate electrode has a length of 0.09 μm to 0.15 μm.

13. The method according to claim 11, further comprising:
forming another salicide layer on the gate electrode.

14. The method according to claim 8, wherein thermally treating the disposable layer is conducted at 900° C. to 1000° C. with a processing gas comprising N₂.

15. The method according to claim 8, wherein the preliminary structure has a PMOS area comprising the two source/drain areas and the gate structure and a NMOS area,
wherein, in forming the disposable layer, the disposable layer is formed on both the PMOS area and the NMOS area, and
wherein forming the two sacrificial spacers comprises:
removing portions of the disposable layer from the PMOS area such that the source/drain areas and the gate structure are exposed and the two sacrificial spacers formed of the disposable layer are remained on sidewalls of the gate structure.

16. The method according to claim 8, wherein forming the two source/drain regions comprises:
forming two recesses at the two source/drain areas, respectively; and
growing an epitaxial material in the recesses to form the two source/drain regions.

17. The method according to claim 16, wherein forming the two recesses comprises a dry etch step and a wet etch step following the dry etch step,
wherein after the dry etch step, outer bottom portions of the two sacrificial spacers are removed, and
wherein after the wet etch step, each of the two recesses has a hexagonal cross-section with a side extending along corresponding one of the two sacrificial spacers.

18. The method according to claim 8, wherein the epitaxial material is SiGe.

19. The method according to claim 8, wherein forming the two salicide layers comprises:
forming two cap layers on the two source/drain regions, respectively; and
thermally treating such that the two salicide layers are formed.

20. The method according to claim 8, further comprising:
forming two contacts connected to the two source/drain regions, respectively.
